(19) United States
(12) Patent Application Publication
(10) Pub. No.: US 2012/0247802 A1
(43) Pub. Date: Oct. 4, 2012

(54) KEYSWITCH STRUCTURE AND PROTECTIVE CASING USING THE SAME

(76) Inventor: Kai-Hung Wang, Kaohsiung City (TW)

(21) Appl. No.: 13/075,120

(22) Filed: Mar. 29, 2011

(51) Int. Cl. H05K 5/06; H05K 5/00; H01H 13/14

(52) U.S. Cl. 174/50.5; 200/341; 174/50; 174/520

(57) ABSTRACT

A keyswitch structure is implemented in a protective casing for an electronic device. The keyswitch structure includes a flexible part and an insertion part. The flexible part is disposed on a position of the protective casing corresponding to a button of the electronic device. The flexible part includes a pressing portion, a connecting portion connected between the pressing portion and the main body for allowing the pressing portion to move elastically relative to the protective casing, and a protruding portion protruding from the pressing portion for reaching the button. The insertion part is embedded in the protruding portion for pressing the button down cooperatively with the protruding portion when the pressing portion is pressed. The hardness of the insertion part is greater than that of the flexible part.

### BACKGROUND OF THE INVENTION

1. Field of the Invention

The present invention relates to a keyswitch structure and a protective casing using the same, and more particularly, to a keyswitch structure with enhanced structural strength and a protective casing using the same.

2. Description of the Prior Art

As technology advances, various electronic devices including mobile phone, media player (e.g. MP3 player), personal digital assistant (PDA) and so on have been developed to make life more convenient and colorful. In order to protect the electronic device from harm, a user may use a protective casing to accommodate the electronic device. In the prior art, several keyswitch structures are formed on the protective casing at positions corresponding to buttons of the electronic device respectively for contacting with the buttons. Generally, the keyswitch structures are made of flexible material such as rubber in favor for user's operation. However, in many cases, the keyswitch structure made of rubber does not provide enough structural strength to effectively press down the button.

### SUMMARY OF THE INVENTION

The present invention provides a keyswitch structure implemented in a protective casing for an electronic device. The keyswitch structure includes a flexible part disposed on a position of the protective casing corresponding to a button of the electronic device and an insertion part. The flexible part includes a pressing portion, a connecting portion connected between the pressing portion and the protective casing for allowing the pressing portion to move elastically relative to the protective casing, and a protruding portion protruding from the pressing portion for reaching the button. The insertion part is embedded in the protruding portion for pressing the button down cooperatively with the protruding portion when the pressing portion is pressed. The hardness of the insertion part is greater than that of the flexible part.

The present invention further provides a protective casing for an electronic device including a main body and a keyswitch structure connected to the main body. The keyswitch structure includes a flexible part disposed on a position of the protective casing corresponding to a button of the electronic device, and an insertion part. The flexible part includes a pressing portion, a connecting portion connected between the pressing portion and the main body for allowing the pressing portion to move elastically relative to the protective casing, and a protruding portion protruding from the pressing portion for reaching the button. The insertion part is embedded in the protruding portion for pressing the button down cooperatively with the protruding portion when the pressing portion is pressed. The hardness of the insertion part is greater than that of the flexible part.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view of a protective casing operated at a closed state according to a preferred embodiment of the invention.

FIG. 2 is a partial section view of a keyswitch structure in FIG. 1.

FIG. 3 is a perspective view of the protective casing in FIG. 1 from another view angle.

FIG. 4 is a perspective view of the protective casing in FIG. 3 operated at an opened state.

FIG. 5 is an exploded view of a lower cover in FIG. 4.

FIG. 6 is a perspective view illustrating an electronic device accommodated in a first accommodating space.

### DETAILED DESCRIPTION

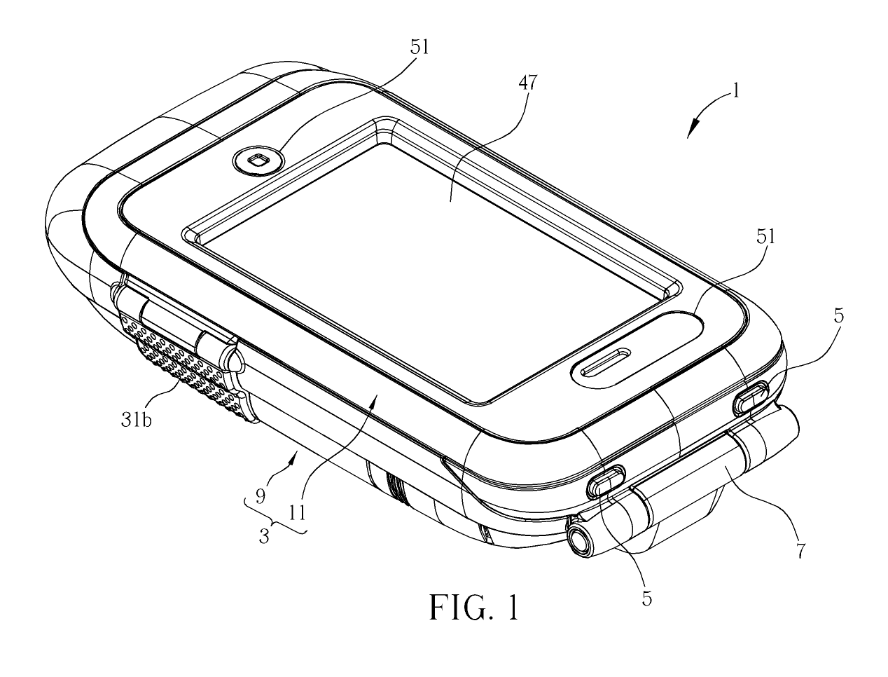

Please refer to FIG. 1, which is a perspective view of a protective casing 1 operated at a closed state according to a preferred embodiment of the invention. As shown in FIG. 1, the protective casing 1 includes a main body 3, a keyswitch structure 5 connected to the main body 3, and a hinge assembly 7. The main body 3 includes the lower cover 9 and an upper cover 11, and the hinge assembly 7 is used for pivotally connecting the upper cover 11 to the lower cover 9.

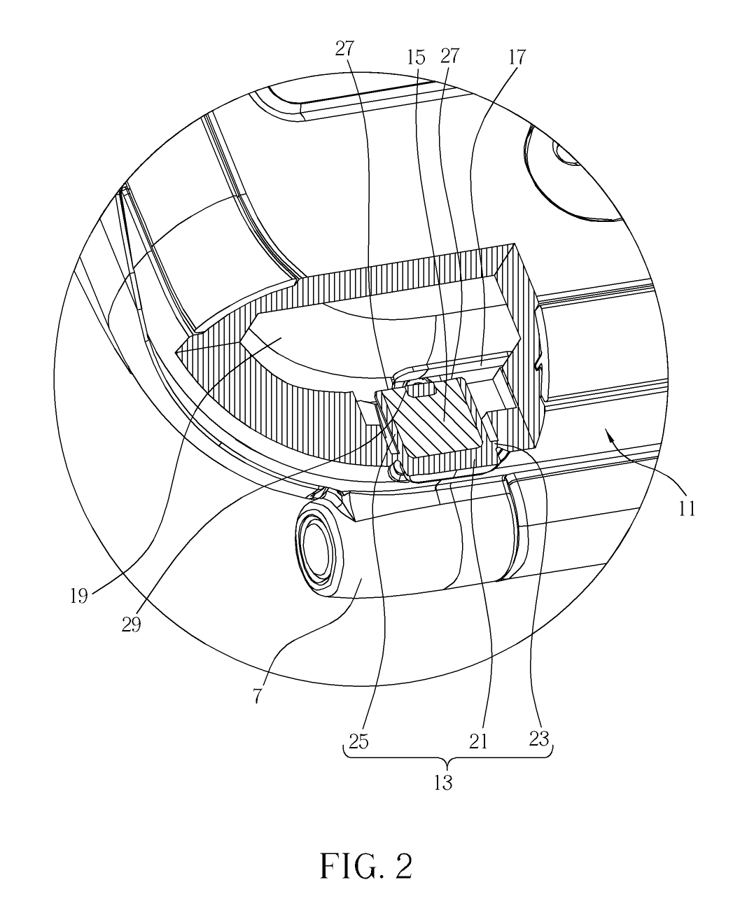

More detailed description for the keyswitch structure 5 is provided as follows. Please refer to FIG. 2, which is a partial section view of the keyswitch structure 5 in FIG. 1. As shown in FIG. 2, the keyswitch structure 5 includes a flexible part 13 and an insertion part 15, wherein the flexible part 13 is disposed on a position of the protective casing 1 corresponding to a button 17 of an electronic device 19. The flexible part 13 includes a pressing portion 21, a connecting portion 23 and a protruding portion 25, and the insertion part 15 is embedded in the protruding portion 25. The pressing portion 21 is used for the user to press, and the protruding portion 25 protrudes from the pressing portion 21 for reaching the button 17. The connecting portion 23 is connected between the pressing portion 21 and the upper cover 11 of the protective casing 1. In this embodiment, the flexible part 13 and the insertion part 15 are formed integrally by an insert-molding process. Any known insert-molding processes can be adapted to insert-molding the flexible part 13 and the insertion part 15.

Since the flexible part 13 is made of flexible material, the connecting portion 23 is capable of elastically deforming. Thus, the connecting portion 23 allows the pressing portion 21 and the protruding portion 25 to move elastically relative to the upper cover 11 when the user presses the pressing portion 21. In such a manner, via elasticity of the connecting portion 23, the protruding portion 25 can move inward to press down the button 17 cooperatively with the insertion part 15 when the user presses the pressing portion 21, and restore its original position when the user releases the pressing portion 21. It should be noticed that the hardness of the insertion part 15 is greater than that of the flexible part 13. Accordingly, the structural strength of the protruding portion 25 is enhanced by embedment of the insertion part 15. As a result, the protruding portion 25 with the insertion part 15 embedded therein is capable of pressing down the button 17 effectively without buckling. In other words, the protruding portion 25 is enhanced in structural strength by the said design so as to resist the reacting force applied by the button 17 during the said pressing process. In practical application, the flexible part 13 is made of thermoplastic urethane (TPU) material, and the insertion part 15 is made of polycarbonate mixed with glass fiber (PC/GF polymer) material.

In order to enhance pressing effect and the button-click feedback, the insertion part 15 has at least one exposed portion 27 (two shown in FIG. 2) corresponding to the button 17 of the electronic device 19. In other words, the insertion part 15 is embedded in the protruding portion 25 in a manner of partially exposing from the protruding portion 25. Accordingly, the exposed portion 27 of the insertion part 15, which is made of material with greater hardness, is in direct contact with the button 17 when the pressing portion 21 is pressed, so as to achieve the purpose of enhancing pressing effect and click feedback. In addition, the design of the insertion part 15 being embedded in the protruding portion 25 is not limited to the above-mentioned embodiment. For example, the insertion part 15 can also be embedded in the protruding portion 25 without any exposed portion.

Furthermore, in this embodiment, for preventing the insertion part 15 from dropping out of the protruding portion 25, at least one recess 29 is formed on the insertion part 15 to allow a part of the protruding portion 25 to be filled therein when the flexible part 13 and the insertion part 15 are formed integrally by the insert-molding process. Thus, the part of the protruding portion 25 filled in the recess 29 constrains movement of the insertion part 15 in the protruding portion 25, so as to fix the insertion part 15 in the protruding portion 25 and prevent the insertion part 15 from dropping out of the protruding portion 25. It should be noticed that the recess 29 is exemplified to be located between the two exposed portions 27 in this embodiment (as shown in FIG. 2). The structure for preventing the insertion part 15 from dropping out is not limited to the recess 29 mentioned above. For example, it can be a hole formed at the center of the insertion part 15, for a part of the protruding portion 25 to be filled therein when the flexible part 13 and the insertion part 15 are formed integrally by the insert-molding process.

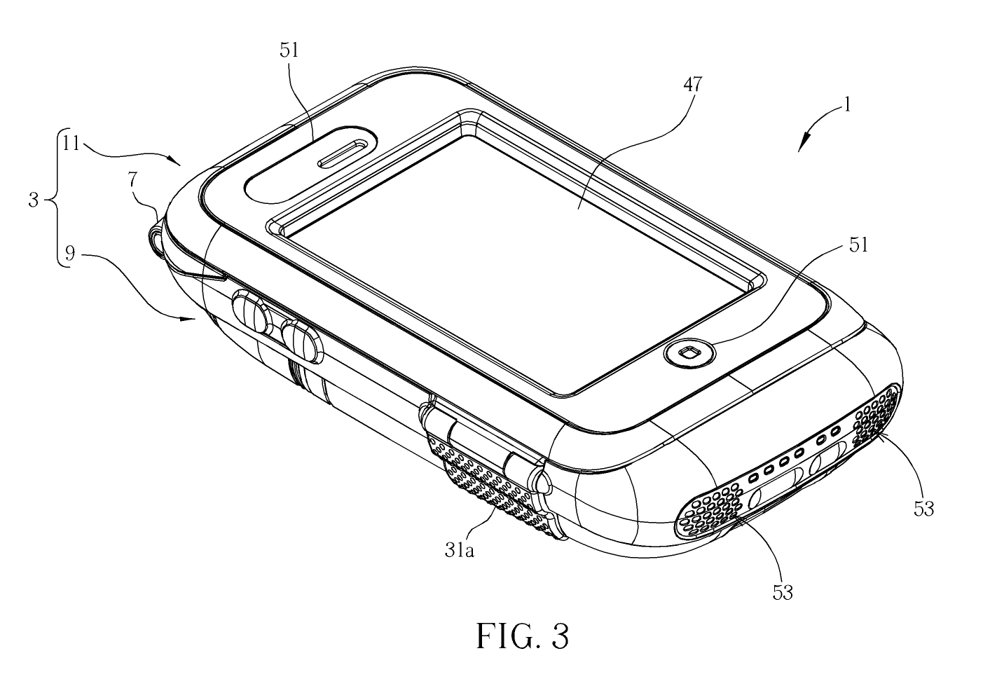

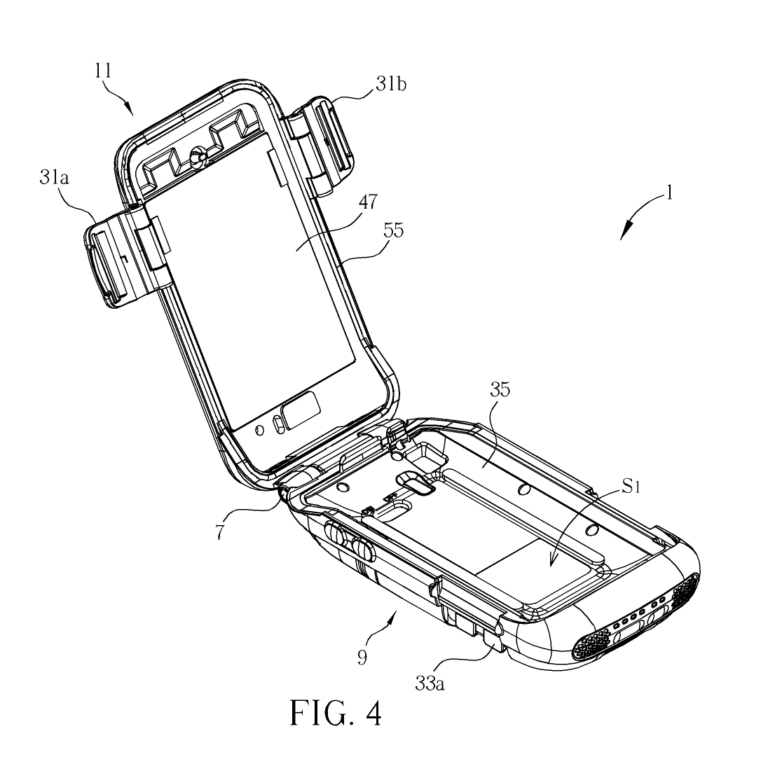

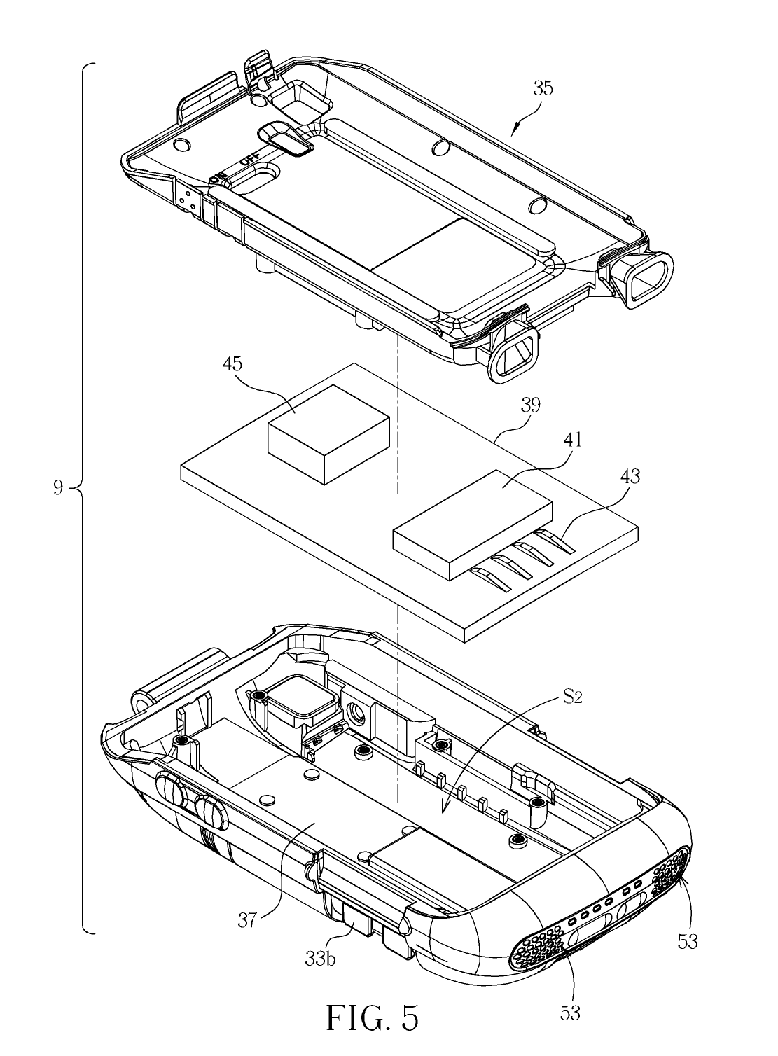

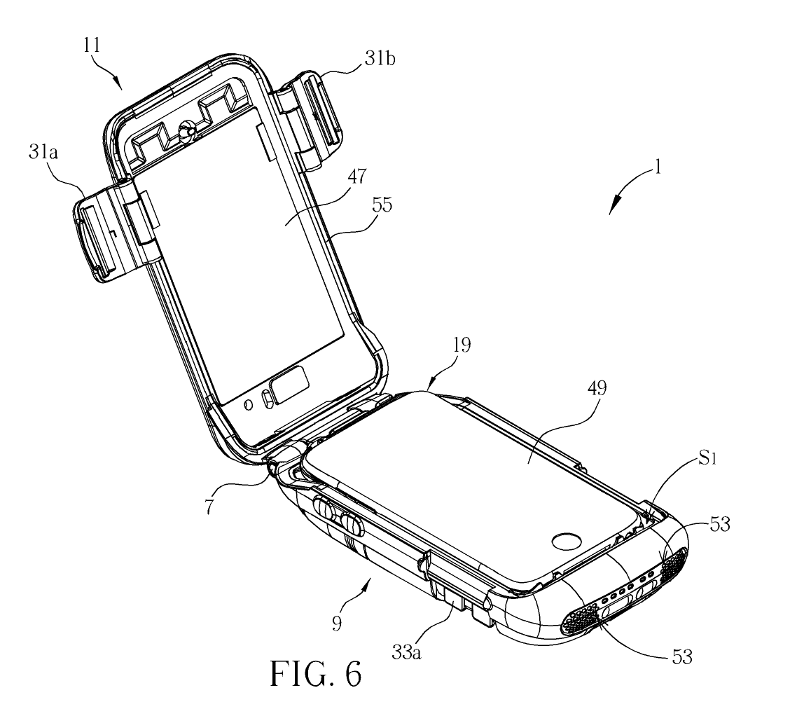

Furthermore, more detailed description for the protective casing 1 is provided as follows. Please refer to FIG. 1 and FIGS. 3 to 6. FIG. 3 is a perspective view of the protective casing 1 in FIG. 1 from another view angle. FIG. 4 is a perspective view of the protective casing 1 in FIG. 3 operated at an opened state. FIG. 5 is an exploded view of the lower cover 9 in FIG. 4. FIG. 6 is a perspective view illustrating the electronic device 19 accommodated in a first accommodating space S₁.

As shown in FIGS. 3 to 6, the upper cover 11 may include two fastener members 31a, 31b pivotally connected to opposite sides of the upper cover 11, the lower cover 9 may include two fastener structures 33a, 33b formed on opposite sides of the lower cover 9, and the two fastener members 31a, 31b can be detachably fastened on the two fastener structures 33a, 33b respectively. It should be noted that there is only one fastener structure 33a shown in FIG. 4 due to the view angle. When the protective casing 1 is operated in the closed state shown in FIGS. 1 and 2, the two fastener members 31a, 31b are fastened on the two fastener structures 33a, 33b respectively. On the other hand, when the protective casing 1 is operated in the opened state shown in FIG. 4, the two fastener members 31a, 31b are detached from the two fastener structures 33a, 33b respectively and the upper cover 11 can rotate with respect to the lower cover 9 via the hinge assembly 7. Accordingly, a user can operate the protective casing 1 between the closed state and the opened state.

In addition, the lower cover 9 may further include a partition member 35, and the upper cover 11 cooperates with the lower cover 9 to form the first accommodating space S₁ therebetween for housing the electronic device 19, wherein the first accommodating space S₁ is above the partition member 35. In this embodiment, the electronic device 19 is preferably, but not limited to, a mobile phone. It can also be a media player (e.g. MP3 player), a personal digital assistant (PDA) and so on. As shown in FIG. 5, a second accommodating space S₂ is between the partition member 35 and a bottom 37 of the lower cover 9. In this embodiment, the protective casing 1 may further include a circuit board 39 and a power supply unit 41 disposed in the second accommodating space S₂. The power supply unit 41 is electrically connected to the circuit board 39. When the electronic device 19 is accommodated in the first accommodating space S₁, a connector (not shown) of the electronic device 19 is electrically connected to a connector 43 of the circuit board 39, such that the power supply unit 41 can supply power to the electronic device 19. In practical applications, the power supply unit 41 is preferably a battery.

As shown in FIG. 5, the protective casing 1 may further include a positioning unit 45 disposed in the second accommodating space S₂ and electrically connected to the circuit board 39. In practical applications, the positioning unit 45 is preferably a Global Positioning System (GPS). The positioning unit 45 can be used to assist the electronic device 19 in positioning itself once the electronic device 19 cannot position itself precisely.

As shown in FIG. 6, the upper cover 11 further includes a transparent sheet 47 (e.g. PET film). When the electronic device 19 is accommodated in the first accommodating space S₁ and the protective casing 1 is operated in the closed state (as shown in FIG. 1), a touch panel 49 of the electronic device 19 abuts against the transparent sheet 47. Accordingly, the user may operate the touch panel 49 via the transparent sheet 47.

As shown in FIG. 3, there is at least one hole 51 formed on the upper cover 11 for specific purposes (e.g. light emitting hole, button hole, etc.), and the upper cover 11 may include at least one waterproof member (e.g. waterproof film or waterproof glue, not shown) disposed within the hole 51 respectively, so as to prevent water from entering the protective casing 1 via the hole 51. Furthermore, there is at least one hole 53 formed on the lower cover 9 for specific purposes (e.g. speaker hole, microphone hole, etc.), and the lower cover 9 may also include at least one waterproof member (e.g. waterproof film or waterproof glue, not shown) disposed within the hole 53 respectively, so as to prevent water from entering the protective casing 1 via the hole 53. Moreover, the upper cover 11 may include a ring-shaped waterproof member 55 disposed on an inner side of the upper cover 11, as shown in FIG. 4. When the protective casing 1 is operated in the closed state shown in FIG. 2, the ring-shaped waterproof member 55 can prevent water from entering the protective casing 1 via the junction between the upper cover 11 and the lower cover 9.

Compared with the prior art, the present embodiments of the invention embeds the insertion part in the protruding portion of the flexible part so as to enhance the structural strength of the keyswitch structure. Therefore, the keyswitch structure of the present invention is capable of pressing the button of the electronic device more effectively and provides more accurate click feedback as well.

Those skilled in the art will readily observe that numerous modifications and alterations of the device and method may be made while retaining the teachings of the invention.

What is claimed is:

1. A keyswitch structure implemented in a protective casing for an electronic device, the keyswitch structure comprising:
a flexible part disposed on a position of the protective casing corresponding to a button of the electronic device, the flexible part comprising:
a pressing portion;
a connecting portion connected between the pressing portion and the protective casing for allowing the pressing portion to move elastically relative to the protective casing; and
a protruding portion protruding from the pressing portion for reaching the button; and
an insertion part embedded in the protruding portion for pressing the button down cooperatively with the protruding portion when the pressing portion is pressed;
wherein the hardness of the insertion part is greater than that of the flexible part.

2. The keyswitch structure of claim 1, wherein the flexible part is made of thermoplastic urethane (TPU) material, and the insertion part is made of polycarbonate mixed with glass fiber (PC/GF polymer) material.

3. The keyswitch structure of claim 1, wherein the flexible part and the insertion part are formed integrally by an insert-molding process.

4. The keyswitch structure of claim 1, wherein at least one recess is formed on the insertion part, and a part of the protruding portion is filled in the recess for fixing the insertion part in the protruding portion.

5. The keyswitch structure of claim 1, wherein the insertion part is embedded in the protruding portion in a manner of partially exposing from the protruding portion, and an exposed portion of the insertion part corresponds to the button of the electronic device.

6. A protective casing for an electronic device, the protective casing comprising:
a main body; and
a keyswitch structure connected to the main body, the keyswitch structure comprising:
a flexible part disposed on a position of the protective casing corresponding to a button of the electronic device, the flexible part comprising:
a pressing portion;
a connecting portion connected between the pressing portion and the main body for allowing the pressing portion to move elastically relative to the protective casing; and
a protruding portion protruding from the pressing portion for reaching the button; and
an insertion part embedded in the protruding portion for pressing the button down cooperatively with the protruding portion when the pressing portion is pressed;
wherein the hardness of the insertion part is greater than that of the flexible part.

7. The protective casing of claim 6, wherein the flexible part is made of thermoplastic urethane (TPU) material, and the insertion part is made of polycarbonate mixed with glass fiber (PC/GF polymer) material.

8. The protective casing of claim 6, wherein the flexible part and the insertion part are formed integrally by an insert-molding process.

9. The protective casing of claim 6, wherein the insertion part is embedded in the protruding portion in a manner of partially exposing from the protruding portion, and an exposed portion of the insertion part corresponds to the button of the electronic device.

10. The protective casing of claim 6, wherein the main body comprises:
a lower cover; and
an upper cover cooperating with the lower cover to form a first accommodating space therebetween for housing the electronic device.

11. The protective casing of claim 10, further comprising a hinge assembly for pivotally connecting the upper cover and the lower cover.

12. The protective casing of claim 10, wherein the upper cover comprises a transparent sheet, and a display surface of the electronic device abuts against the transparent sheet when the electronic device is accommodated in the first accommodating space.

13. The protective casing of claim 10, wherein the upper cover comprises two fastener members pivotally connected to opposite sides of the upper cover, the lower cover comprises two fastener structures formed on opposite sides of the lower cover, and the two fastener members are detachably fastened on the two fastener structures respectively.

14. The protective casing of claim 10, wherein the lower cover comprises a partition member, the first accommodating space is above the partition member, and a second accommodating space is between the partition member and a bottom of the lower cover.

15. The protective casing of claim 14, further comprising a circuit board and a power supply unit disposed in the second accommodating space, the power supply unit is electrically connected to the circuit board and is used for supplying power to the electronic device when the electronic device is accommodated in the first accommodating space.

16. The protective casing of claim 14, further comprising a positioning unit disposed in the second accommodating space and electrically connected to the circuit board.

17. The protective casing of claim 10, wherein at least one hole is formed on the upper cover, and the upper cover comprises at least one waterproof member disposed within the at least one hole respectively.

18. The protective casing of claim 10, wherein the upper cover comprises a ring-shaped waterproof member disposed on an inner side of the upper cover.
